(19) United States
(12) Patent Application Publication
(10) Pub. No.: US 2012/0250265 A1
(43) Pub. Date: Oct. 4, 2012

(54) CIRCUIT MODULE MANUFACTURING METHOD, CIRCUIT MODULE, AND ELECTRONIC APPARATUS INCLUDING CIRCUIT MODULE

(75) Inventor: Toshiya KAWATE, Nagaokakyo-shi (JP)

(73) Assignee: MURATA MANUFACTURING CO., LTD., Nagaokakyo-shi (JP)

(21) Appl. No.: 13/525,573

(22) Filed: Jun. 18, 2012

Related U.S. Application Data
(63) Continuation of application No. PCT/JP2010/072199, filed on Dec. 10, 2010.

(30) Foreign Application Priority Data
Dec. 22, 2009 (JP) 2009-290919

(51) Int. Cl. H05K 3/00; H05K 7/00

(52) U.S. Cl. 361/729; 361/728; 29/831

(57) ABSTRACT

A method of manufacturing a plurality of circuit modules includes cutting a mother board including a plurality of electronic components mounted on at least a single surface thereof, and cutting out a plurality of circuit boards from the mother board. A plurality of terminal electrode boards, each of which is arranged so as to straddle at least the circuit boards that are adjacent to each other, are mounted onto one surface of the mother board. The mother board including the terminal electrode boards mounted on the one surface, and the electronic components, mounted on the at least single surface, is diced at positions where the circuit boards are to be cut out.

### BACKGROUND OF THE INVENTION

1. Field of the Invention

The present invention relates to a method of manufacturing a plurality of circuit modules by cutting a mother board including a plurality of electronic components mounted on at least a single surface thereof, and cutting out a plurality of circuit boards from the mother board, a circuit module, and an electronic apparatus including a circuit module.

2. Description of the Related Art

Recent advances in the miniaturization and weight reduction of electronic apparatuses have also led to a growing demand for miniaturization and weight reduction of circuit modules mounted to the electronic apparatuses themselves. Accordingly, miniaturization and weight reduction of circuit modules are achieved by using lead terminals, solder balls, cavity structures, or the like to mount electronic components on both surfaces. A circuit module manufacturing method which mounts electronic components on both surfaces by using a cavity structure is disclosed in each of Japanese Unexamined Patent Application Publication No. 2008-206173 and Japanese Unexamined Patent Application Publication No. 2009-123869.

In the circuit module manufacturing method disclosed in Japanese Unexamined Patent Application Publication No. 2008-206173, a first mother board from which to cut out a plurality of circuit boards, and a second mother board from which to cut out a plurality of terminal electrode boards each having a hole at the center are prepared, the first mother board and the second mother board are bonded together, and the first and second mother boards bonded together are diced. In the circuit module manufactured by the circuit module manufacturing method disclosed in Japanese Unexamined Patent Application Publication No. 2008-206173, a cavity structure is defined by mounting the terminal electrode board having a hole at the center onto the circuit board, and electronic components are mounted on both surfaces of the circuit board.

In the circuit module manufacturing method disclosed in Japanese Unexamined Patent Application Publication No. 2009-123869, four terminal electrode boards are mounted onto a mother board from which to cut out a plurality of circuit boards, along the outer periphery of each of the circuit boards, and then the mother board with the terminal electrode boards mounted is diced. In the circuit module manufactured by the circuit module manufacturing method disclosed in Japanese Unexamined Patent Application Publication No. 2009-123869, a cavity structure is defined by mounting four terminal electrodes along the outer periphery of the circuit board, and electronic components are mounted on both surfaces of the circuit board.

In the circuit module manufacturing method disclosed in Japanese Unexamined Patent Application Publication No. 2008-206173, the circuit module is manufactured by preparing the first mother board and the second mother board having substantially the same area, and bonding the first mother board and the second mother board together. Consequently, only the same number of terminal electrode boards as the number of circuit boards cut out from the first mother board can be cut out from the second mother board. Further, the terminal electrode board to be cut out from the second mother board has a hole at the center, and thus there is a large portion that is not used as the terminal electrode board. Consequently, the circuit module having a cavity structure defined by mounting the terminal electrode board onto the circuit board cannot be manufactured at low cost due to increased material cost.

The circuit module manufacturing method disclosed in Japanese Unexamined Patent Application Publication No. 2009-123869 requires that four elongated terminal electrode boards be individually mounted along the outer periphery of each of the circuit boards. Consequently, the terminal electrode board may tilt, leading to poor coplanarity of the circuit module.

### SUMMARY OF THE INVENTION

In view of the above circumstances, preferred embodiments of the present invention provide a circuit module manufacturing method, a circuit module, and an electronic apparatus including a circuit module, which enable low cost manufacture while minimizing material cost by reducing a portion that is not used as a terminal electrode board in a mother board from which to cut out the terminal electrode board, and can improve the coplanarity of the circuit module.

A circuit module manufacturing method according to a first preferred embodiment of the present invention is a method of manufacturing a plurality of circuit modules by cutting a mother board including a plurality of electronic components mounted on at least a single surface thereof, and cutting out a plurality of circuit boards from the mother board, the method including a first step of mounting a plurality of terminal electrode boards onto one surface of the mother board, the terminal electrode boards each being arranged so as to straddle at least the circuit boards that are adjacent to each other, and a second step of cutting the mother board including the terminal electrode boards mounted on the one surface and the electronic components mounted on the at least single surface, at positions where the circuit boards are to be cut out.

According to the first preferred embodiment of the present invention, a plurality of terminal electrode boards are mounted on one surface of the mother board from which to cut out a plurality of circuit boards. As a result, the same number of terminal electrode boards as the number of circuit boards to be cut out from a single mother board need not be cut out from a single mother board. It is thus possible to select a shape or geometry that can maximize the number of terminal electrode boards that can be cut out from a single mother board. Since the portion of the mother board not used as the terminal electrode board is reduced, it is possible to minimize material cost, and manufacture the circuit module at low cost. Also, by arranging the terminal electrode board so as to straddle at least a plurality of adjacent circuit boards, it is possible to mount a single terminal electrode board onto a plurality of circuit boards. Thus, as compared with the case of mounting the terminal electrode board individually onto each of the circuit boards, the flatness of the terminal electrode board increases, thereby improving the coplanarity of the circuit module.

In the circuit module manufacturing method according to a second preferred embodiment of the present invention, in the first preferred embodiment of the present invention, each of the circuit boards to be cut out from the mother board preferably has a rectangular or substantially rectangular outer shape in plan view, and in the first step, each of the terminal electrode boards is preferably arranged along each of two opposite sides on an outer periphery of each of the circuit boards. Therefore, the number of man-hours needed to mount each terminal electrode board onto the mother board decreases, thereby making it possible to minimize operation cost and manufacture the circuit module at low cost.

In the circuit module manufacturing method according to a third preferred embodiment of the present invention, in the first preferred embodiment of the present invention, each of the circuit boards to be cut out from the mother board preferably has a rectangular or substantially rectangular outer shape in plan view, and in the first step, each of the terminal electrode boards is arranged along each of four sides on an outer periphery of each of the circuit boards. Therefore, it is possible to manufacture a circuit module including as many terminal electrodes that can bond to the terminals of an external apparatus as possible.

In the circuit module manufacturing method according to a fourth preferred embodiment of the present invention, in any one of the first to third preferred embodiments of the present invention, each of the terminal electrode boards preferably includes a plurality of terminal electrodes, and in the first step, each of the terminal electrode boards is mounted onto the mother board while being arranged so that there are a same number of the terminal electrodes for each of the circuit boards. Therefore, when mounting the terminal electrode board onto the mother board, the stress applied to the terminal electrode board in each of the circuit boards by the bonding force between the terminal electrode board and the mother board becomes uniform. As a result, the positional accuracy of the terminal electrode board with respect to the circuit board improves.

In the circuit module manufacturing method according to a fifth preferred embodiment of the present invention, in any one of the first to fourth preferred embodiments of the present invention, each of the terminal electrodes included in each of the terminal electrode boards preferably is a via-hole conductor having a conductive paste applied to at least an inner wall surface of a via-hole provided in each of the terminal electrode boards. Therefore, electrical continuity is secured between the terminal electrode located on the side mounted to the circuit board, and the terminal electrode on the opposite side, thereby facilitating mounting of the circuit board to an external apparatus.

In the circuit module manufacturing method according to a sixth preferred embodiment of the present invention, in any one of the first to fifth preferred embodiments of the present invention, in each of the terminal electrode boards, each of the terminal electrodes is exposed on a side surface provided on a same plane as an outer side surface of each of the circuit boards. Thus, when mounting the circuit module to an external apparatus, the bond state between the terminal electrode of the terminal electrode board and the external apparatus can be visually observed easily, thereby making it possible to check the bond state between the circuit module and the external apparatus.

An electronic apparatus according to a seventh preferred embodiment of the present invention includes any of the circuit modules manufactured by using the circuit module manufacturing method according to any of the first through sixth preferred embodiments of the present invention. Therefore, the electronic apparatus can be manufactured at low cost while achieving miniaturization and weight reduction.

A circuit module according to an eighth preferred embodiment of the present invention includes a circuit board, a plurality of electronic components mounted on at least a single surface of the circuit board, and a plurality of terminal electrode boards mounted on one surface of the circuit board so that a side surface of each of the terminal electrode boards is arranged on a same plane as an outer side surface of the circuit board. Therefore, the terminal electrode board can be also diced together when cutting out a plurality of circuit boards from the mother board, thereby making it possible to obtain a circuit module with good dimensional accuracy of its outer side surface.

In the circuit module according to a ninth preferred embodiment of the present invention, in the eighth preferred embodiment of the present invention, the circuit board preferably has a rectangular or substantially rectangular outer shape in plan view, and each of the terminal electrode boards is arranged along each of two opposite sides on an outer periphery of the circuit board. Therefore, the number of man-hours needed to mount each terminal electrode board onto the mother board decreases, thereby making it possible to minimize operation cost and manufacture the circuit module at low cost.

An electronic apparatus according to a tenth preferred embodiment of the present invention includes a circuit module according to the eighth or ninth preferred embodiment of the present invention. Therefore, the electronic apparatus can be manufactured at low cost while achieving miniaturization and weight reduction.

According to the circuit module manufacturing method according to various preferred embodiments of the present invention, a plurality of terminal electrode boards are mounted on one surface of the mother board from which to cut out a plurality of circuit boards. As a result, the same number of terminal electrode boards as the number of circuit boards to be cut out from a single mother board need not be cut out from a single mother board. It is thus possible to select a shape or geometry that can maximize the number of terminal electrode boards that can be cut out from a single mother board. Since the portion of the mother board not used as the terminal electrode board is reduced, it is possible to minimize material cost, and manufacture the circuit module at low cost. Also, by arranging the terminal electrode board so as to straddle at least a plurality of adjacent circuit boards, it is possible to mount a single terminal electrode board onto a plurality of circuit boards. Thus, as compared with the case of mounting the terminal electrode board individually onto each of the circuit boards, the flatness of the terminal electrode board increases, thereby improving the coplanarity of the circuit module.

Also, the circuit module according to various preferred embodiments of the present invention includes a plurality of terminal electrode boards mounted on one surface of the circuit board so that the side surface of each of the terminal electrode boards is arranged on the same plane as the outer side surface of the circuit board. Therefore, the terminal electrode board can be also diced together when cutting out a plurality of circuit boards from the mother board, thereby improving the dimensional accuracy of the outer side surface of the circuit module obtained. Further, the electronic apparatus according to various preferred embodiments of the present invention includes the circuit module manufactured by the circuit module manufacturing method according to a preferred embodiment of the present invention, or the circuit module according to a preferred embodiment of the present invention. Therefore, the electronic apparatus can be manufactured at low cost while achieving miniaturization and weight reduction.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view illustrating the configuration of a circuit module according to Preferred Embodiment 1 of the present invention.

FIG. 2 is a perspective view of a mother board provided with a terminal electrode.

FIG. 3 is perspective view of a plurality of terminal electrode boards that have been cut out from a mother board.

FIG. 4 is a perspective view of a mother board provided with a bonding pad and having an electronic component mounted on one surface.

FIG. 5 is a perspective view of a mother board on which a plurality of terminal electrode boards are mounted.

FIG. 6 is a perspective view of a mother board placed so that the surface on which an electronic component and a terminal electrode board are mounted contacts a support base.

FIG. 7 is a cross-sectional view of a mother board taken along the line A-A illustrated in FIG. 6.

FIG. 8 is a perspective view of a mother board with an electronic component mounted on a bonding pad.

FIG. 9 is a cross-sectional view of a mother board taken along the line B-B illustrated in FIG. 8.

FIG. 10 is a perspective view of a mother board diced at a position where each circuit board is to be cut out.

FIG. 11 is a cross-sectional view of a mother board taken along the line C-C illustrated in FIG. 10.

FIG. 12 is a graph illustrating the relationship between the number of circuit modules that can be obtained from a single mother board, and the number of man-hours needed to bond the mother board and each terminal electrode board together.

FIG. 13 is a cross-sectional view illustrating the configuration of a circuit module according to Preferred Embodiment 2 of the present invention.

FIG. 14 is a perspective view of a terminal electrode board according to Preferred Embodiment 2 of the present invention.

FIG. 15 is a perspective view of a mother board on which a plurality of terminal electrode boards are mounted, according to Preferred Embodiment 3 of the present invention.

FIG. 16 is a perspective view of a mother board on which a plurality of terminal electrode boards are mounted, according to Preferred Embodiment 4 of the present invention.

### DETAILED DESCRIPTION OF THE PREFERRED EMBODIMENTS

Hereinafter, preferred embodiments of the present invention are described in detail with reference to the drawings.

### Preferred Embodiment 1

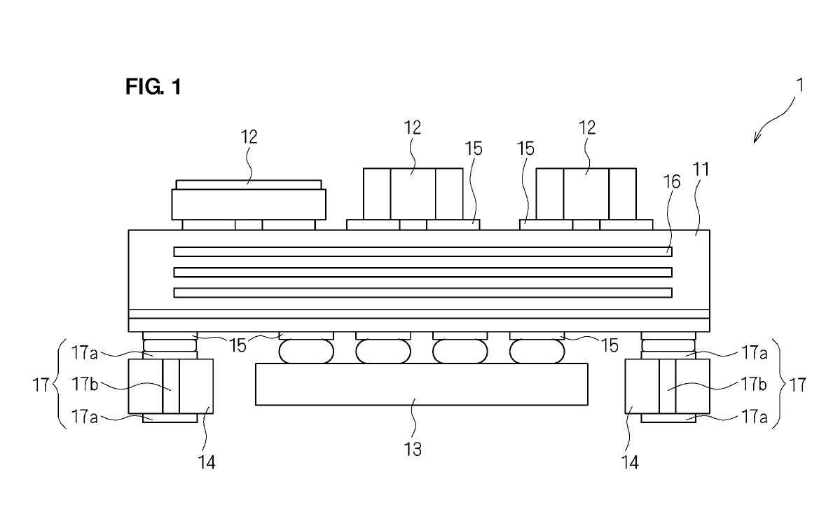

FIG. 1 is a cross-sectional view illustrating the configuration of a circuit module according to Preferred Embodiment 1 of the present invention. The circuit module 1 according to Preferred Embodiment 1 of the present invention includes a circuit board 11 preferably made of ceramic, glass, epoxy resin, or the like, electronic components 12, 13 such as, for example, semiconductor devices, resistors, or SAW filters mounted on both surfaces of the circuit board 11, and a terminal electrode board 14 mounted on the underside (one surface) of the circuit board 11. The electronic components 12, 13 may not necessarily be mounted on both surfaces of the circuit board 11. It suffices that the electronic components 12, 13 be mounted on at least a single surface of the circuit board 11, for example.

The circuit board 11 preferably has a rectangular or substantially rectangular outer shape in plan view. The circuit board 11 includes a bonding pad 15 to electrically bond the circuit board 11 to the electronic components 12, 13 mounted on both surfaces, and a wiring layer 16 provided inside the circuit board 11 to establish electrical connection between the bonding pad 15 and the bonding pad 15 in a predetermined pattern. The bonding pad 15 of the circuit board 11, and the terminals of the electronic component 12, 13 are bonded together by a bonding wire, solder, or the like, for example.

The terminal electrode board 14 preferably is made of ceramic, glass, epoxy resin, or the like, and includes a plurality of terminal electrodes 17. The terminal electrode 17 includes a bonding pad 17a provided on both surfaces of the terminal electrode board 14, and a via-hole conductor 17b to establish electrical bonding between the bonding pad 17a and the bonding pad 17a. The via-hole conductor 17b is formed preferably by applying a conductive paste to at least the inner wall surface of a via-hole provided in the terminal electrode board 14. One side of the terminal electrode 17 is electrically bonded to the bonding pad 15 provided on the circuit board 11, and the other side is electrically bonded to an external apparatus (not illustrated). If the via-hole conductor 17b is to be directly bonded to the bonding pad 15 or the like, the terminal electrode may not be provided with the bonding pad 17a but may be provided with only the via-hole conductor 17b.

The terminal electrode board 14 is arranged and mounted at either end of one surface of the circuit board 11. The electronic component 13 is mounted onto a portion of the circuit board 11 sandwiched between the terminal electrode board 14 and the terminal electrode board 14 mounted at both ends of one surface of the circuit board 11. The side surface of the terminal electrode board 14 is arranged on the same plane as the outer side surface of the circuit board 11. Thus, the terminal electrode board 14 can be also diced together when cutting out a plurality of circuit boards 11 from a mother board, thereby improving the dimensional accuracy of the outer side surface of the circuit module 1 obtained. After the electronic components 12, 13 are mounted onto the circuit board 11, one or both surfaces of the circuit board 11 may be sealed with synthetic resin or the like, for example, so as to cover the electronic components 12, 13.

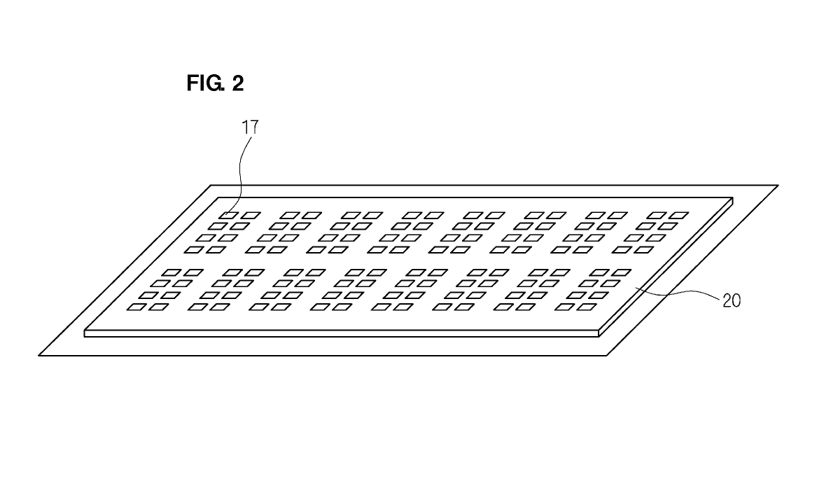

FIGS. 2 to 11 are perspective views or cross-sectional views for explaining a non-limiting example of a method of manufacturing the circuit module 1 according to Preferred Embodiment 1 of the present invention. First, the step of forming the terminal electrode board 14 is described. FIG. 2 is a perspective view of a mother board provided with the terminal electrode 17. FIG. 2 illustrates the step of forming a plurality of sets of terminal electrodes 17 arrayed in two columns and four rows, for example, on a mother board 20 from which to cut out a plurality of terminal electrode boards 14. The array of the terminal electrodes 17 to be formed on the mother board 20 is not limited to an array of two columns and four rows but may be any array as long as it is possible to secure the number of terminal electrodes 17 required for the circuit module 1. The terminal electrode 17 is formed as a via-hole conductor obtained by forming a via-hole in the mother board 20, and applying a conductive paste to at least the inner wall surface of the via-hole formed. By forming the terminal electrode 17 as a via-hole conductor, electrical continuity is secured between the terminal electrode 17 located on the side mounted to the circuit board 11, and the terminal electrode 17 on the opposite side, thereby facilitating mounting of the circuit module 1 to an external apparatus.

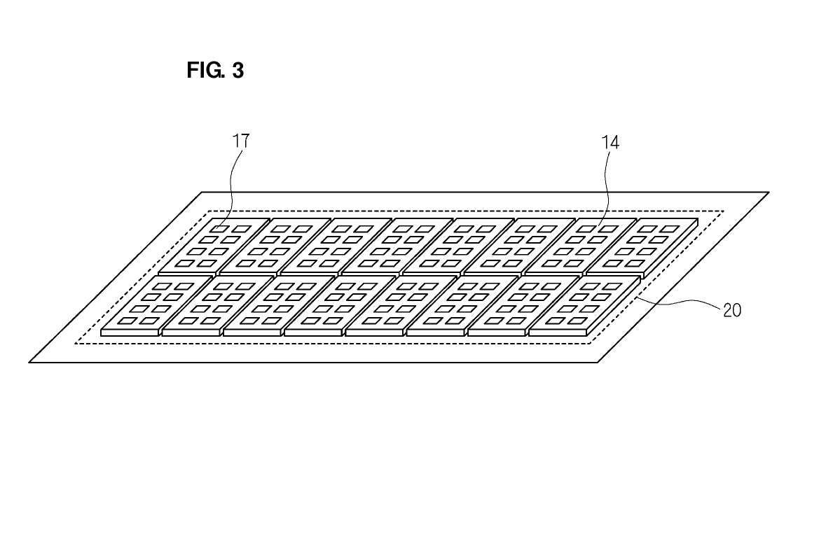

FIG. 3 is perspective view of a plurality of terminal electrode boards 14 that have been cut out from the mother board 20. FIG. 3 illustrates the step of cutting the mother board 20 with a dicer or the like to thereby cut out a plurality of terminal electrode boards 14 from the mother board 20. Each of the terminal electrode boards 14 that have been cut out preferably has a rectangular parallelepiped shape, and has the terminal electrodes 17 arrayed in two columns and four rows, for example. The shape of the terminal electrode board 14 to be cut out from the mother board 20 is not limited to a rectangular parallelepiped but may be any shape that enables mounting onto the circuit board 11, and makes it possible to cut out as many terminal electrode boards 14 as possible from the mother board 20.

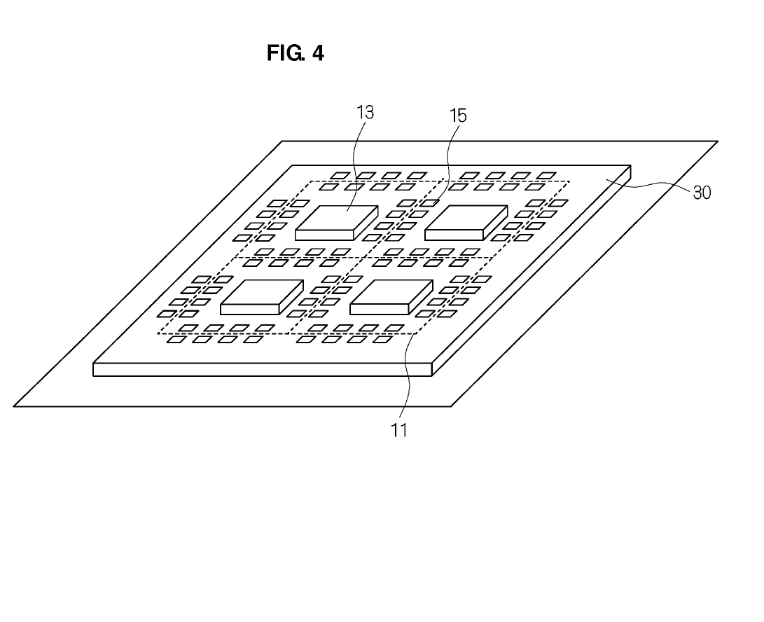

Next, the step of forming the circuit module 1 is described. FIG. 4 is a perspective view of a mother board provided with the bonding pad 15 and having the electronic component 13 mounted on one surface. FIG. 4 illustrates the step of forming a plurality of bonding pads 15 in accordance with a predetermined pattern on a mother board 30 from which to cut out a plurality of circuit boards 11, and mounting the electronic component 13 so as to bond to some of the bonding pads 15 formed. On the mother board 30, the electronic component 13 is mounted for each of the circuit boards 11 so that four circuit boards 11 indicated by broken lines can be cut out from the mother board 30. The electronic component 13 is bonded to the bonding pad 15 formed on the mother board 30 by solder or the like.

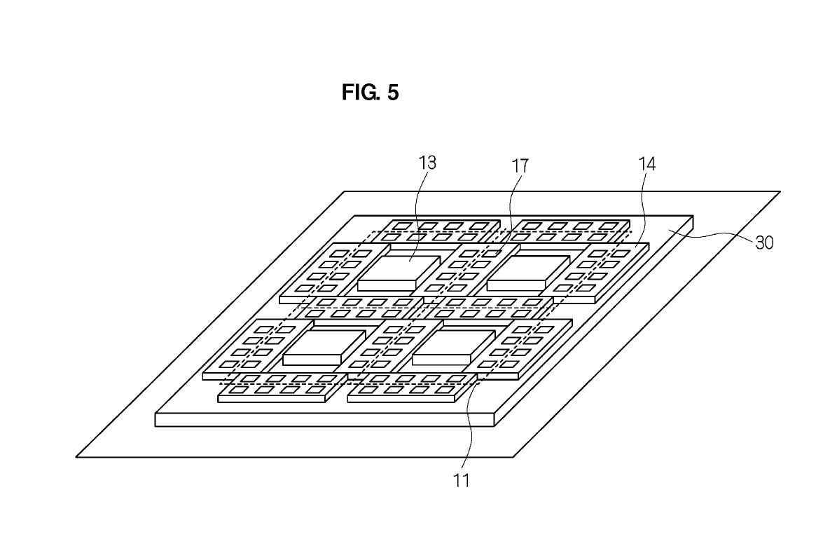

FIG. 5 is a perspective view of the mother board 30 on which a plurality of terminal electrode boards 14 are mounted. FIG. 5 illustrates the step of mounting the terminal electrode board 14 illustrated in FIG. 2 so as to straddle a plurality of adjacent circuit boards 11. The terminal electrode board 14 is arranged along each of four sides on the outer periphery of the circuit board 11 that preferably has a rectangular or substantially rectangular outer shape in plan view, so as to surround the mounted electronic component 13. By arranging the terminal electrode board 14 along each of the four sides on the outer periphery of the circuit board 11, it is possible to manufacture the circuit module 1 having as many terminal electrodes 17 that can bond to the terminals of an external apparatus as possible. The terminal electrode board 14 may not necessarily be arranged along every one of the four sides on the outer periphery of the circuit board 11 that has a rectangular or substantially rectangular outer shape in plan view. It suffices that the terminal electrode board 14 be arranged along at least one side on the outer periphery of the circuit board 11 that has a rectangular or substantially rectangular outer shape in plan view. The terminal electrode board 14 is mounted on the circuit board 11 by bonding the bonding pad 15 formed on the mother board 30 and the terminal electrode 17 together by solder or the like. Since the terminal electrode board 14 is mounted onto the mother board 30 while being arranged so that there are the same number of terminal electrodes 17 for each of the circuit boards 11, when mounting the terminal electrode board 14 onto the mother board 30, the stress applied to the terminal electrode board 14 in each of the circuit boards 11 by the bonding force between the terminal electrode board 14 and the mother board 30 becomes uniform. As a result, the coplanarity of the circuit module 1 further improves, and the positional accuracy of the terminal electrode board 14 with respect to the circuit board 11 improves. For example, in the case of the terminal electrode board 14 having the terminal electrodes 17 arrayed in two columns and four rows, the terminal electrode board 14 is mounted onto the mother board 30 while being arranged so as to straddle a plurality of adjacent circuit boards 11, so that the terminal electrode board 14 can be diced into terminal electrode boards 14 each having the terminal electrodes 17 arrayed in one column and four rows. Since the mounted terminal electrode board 14 has the same number of bonding portions between the bonding pad 15 and the terminal electrode 17 for each of the circuit boards 11, stress is uniformly applied in each of the circuit boards 11.

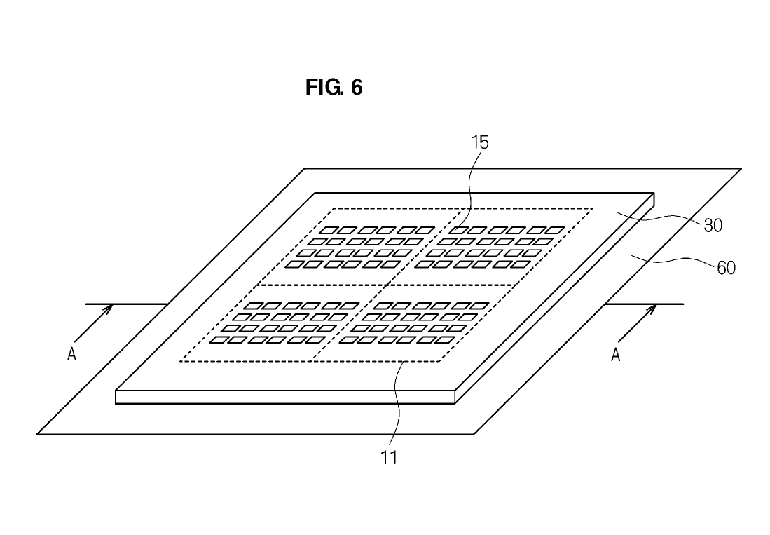

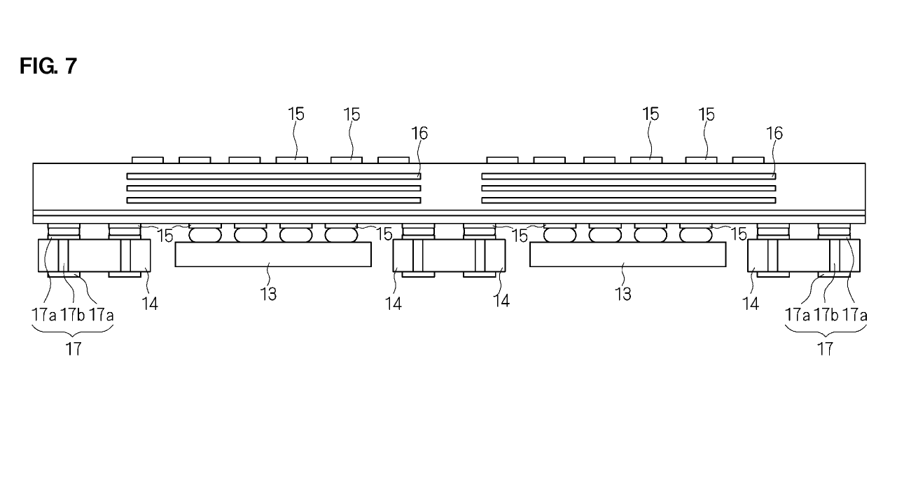

FIG. 6 is a perspective view of the mother board 30 placed so that the surface on which the electronic component 13 and the terminal electrode board 14 are mounted contacts a support base. FIG. 7 is a cross-sectional view of the mother board 30 taken along the line A-A illustrated in FIG. 6. FIGS. 6 and 7 illustrate the step of turning the mother board 30 over with respect to a support base 60 in order to mount the electronic component 12 on the reverse side of the surface on which the electronic component 13 and the terminal electrode board 14 are mounted. A plurality of bonding pads 15 are also formed on the reverse side of the mother board 30. In order to mount the electronic component 12 onto the bonding pad 15, the mother board 30 is placed on the support base 60 so that the surface on which the electronic component 13 and the terminal electrode board 14 are mounted contacts the support base 60. As illustrated in FIG. 7, the terminal electrode board 14 is at substantially the same height as the electronic component 13 from the mother board 30. Accordingly, in a case where the mother board 30 is placed on the support base 60 so that the surface on which the electronic component 13 and the terminal electrode board 14 are mounted contacts the support base 60, the mother board 30 can be placed in a stable manner with respect to the support base 60, thereby facilitating mounting of the electronic component 12 onto the mother board 30.

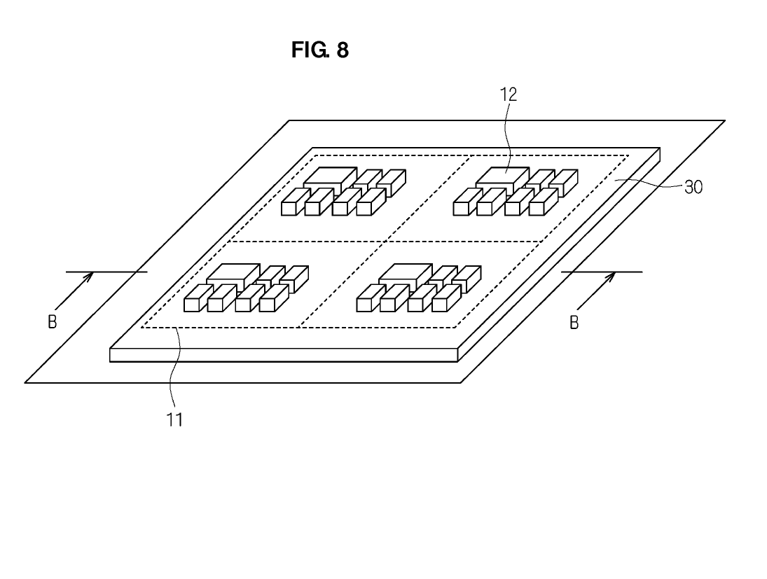

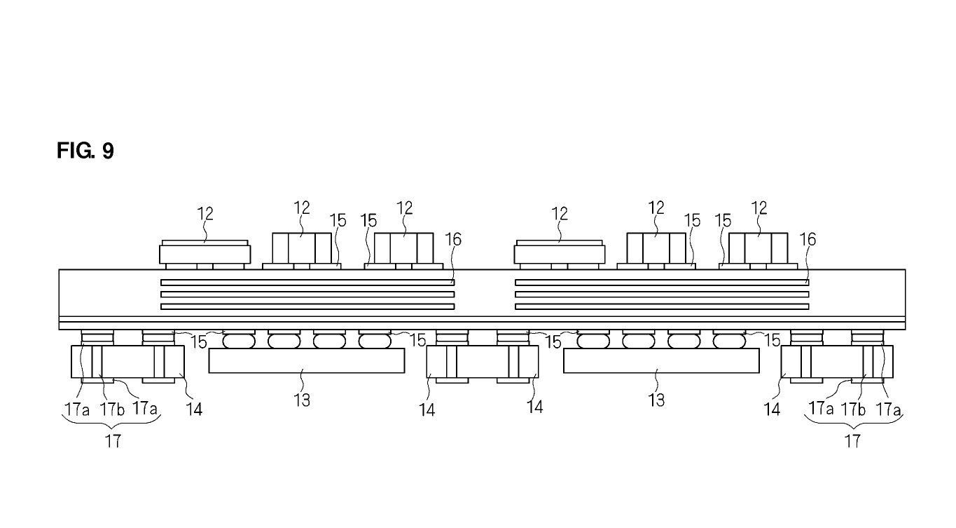

FIG. 8 is a perspective view of the mother board 30 with the electronic component 12 mounted on the bonding pad 15. FIG. 9 is a cross-sectional view of the mother board 30 taken along the line B-B illustrated in FIG. 8. FIGS. 8 and 9 illustrate the step of mounting the electronic component 12 on the reverse side of the surface on which the electronic component 13 and the terminal electrode board 14 are mounted. The electronic component 12 is bonded by solder or the like to the bonding pad 15 formed on the mother board 30. A plurality of electronic components 12 are mounted onto each of the four circuit boards 11 to be cut out from the mother board 30 which are indicated by broken lines. The number, layout, etc. of the electronic components 12 to be mounted onto the circuit board 11 can be set freely as long as physical limitations permit.

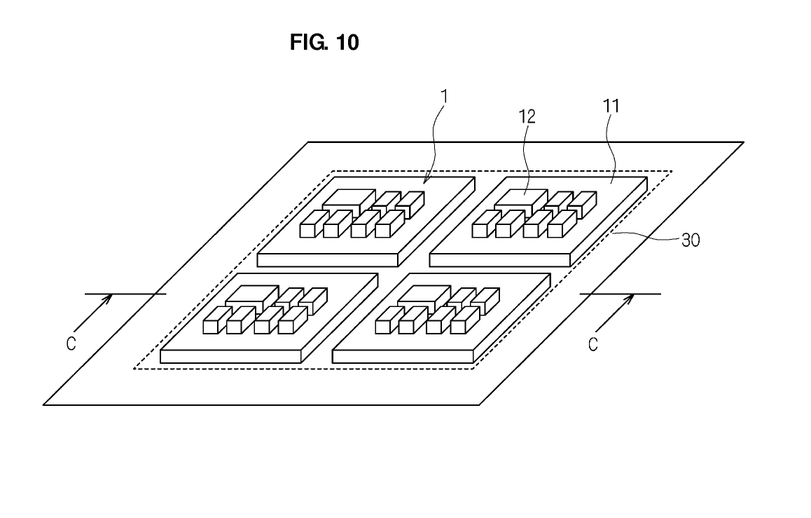

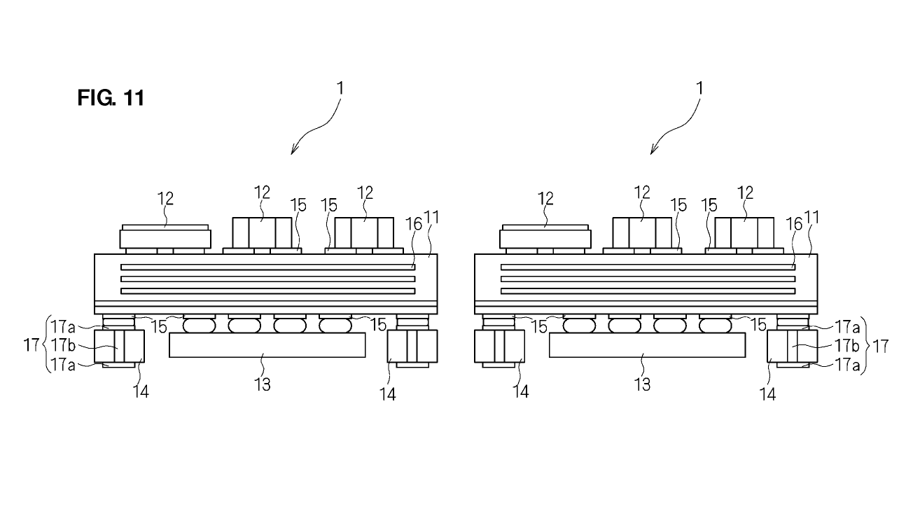

FIG. 10 is a perspective view of the mother board 30 diced at a position where each circuit board 11 is to be cut out. FIG. 11 is a cross-sectional view of the mother board 30 taken along the line C-C illustrated in FIG. 10. FIGS. 10 and 11 illustrate the step of using a dicer or the like to dice the mother board 30 including a plurality of terminal electrode boards 14 mounted on one surface and a plurality of electronic components 12, 13 mounted on both surfaces, at positions where a plurality of circuit boards 11 are to be cut out, thereby breaking the mother board 30 into individual circuit modules 1. Since the terminal electrode board 14 is arranged so as to straddle a plurality of adjacent circuit boards 11, when cutting the mother board 30, the terminal electrode board 14 is also diced into terminal electrode boards 14 each having the terminal electrodes 17 arrayed in one column and four rows. Since the mother board 30 and the terminal electrode board 14 are diced together in the same step, the side surface of the terminal electrode board 14 is provided on the same plane as the outer side surface of the circuit board 11 that has been cut out from the mother board 30.

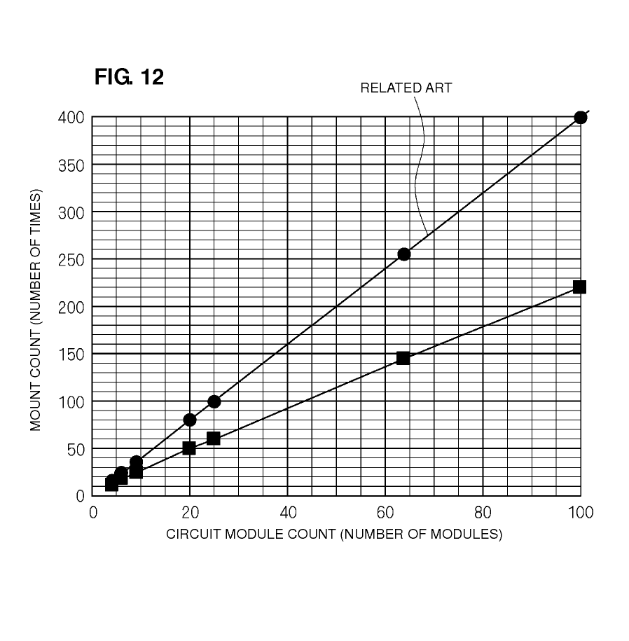

Further, in the method of manufacturing the circuit module 1 according to Preferred Embodiment 1 of the present invention, the terminal electrode board 14 arranged so as to straddle a plurality of adjacent circuit boards 11 is mounted onto the mother board 30. Accordingly, as compared with the case of mounting the terminal electrode board 14 onto each of the circuit boards 11, the number of man-hours needed to bond the mother board 30 and each terminal electrode board 14 together decreases. FIG. 12 is a graph illustrating the relationship between the number of circuit modules 1 that can be obtained from a single mother board 30, and the number of man-hours (mount count) needed to bond the mother board 30 and each terminal electrode board 14 together. The data in FIG. 12 illustrates a case where circuit modules are manufactured by the method of manufacturing the circuit module 1 according to Preferred Embodiment 1, and a case where circuit modules are manufactured by a circuit module manufacturing method according to the related art, with the number of circuit modules taken along the horizontal axis and the number of times each terminal electrode board is bonded to the mother board taken along the vertical axis.

For example, suppose a case where, as illustrated in FIG. 5, four circuit boards 11 are to be cut out from a single mother board 30 (i.e., the number of circuit modules that can be obtained from a single mother board 30 is 4). In this case, in the method of manufacturing the circuit module 1 according to Preferred Embodiment 1, the terminal electrode board 14 is arranged so as to straddle a plurality of adjacent circuit boards 11. Accordingly, the number of terminal electrode boards 14 mounted onto the mother board 30 is 12, and the number of times each terminal electrode board 14 is bonded to the mother board 30 is 12, for example. However, in the circuit module manufacturing method according to the related art, four terminal electrode boards are to be bonded along the four sides on the outer periphery of each of the circuit boards. Accordingly, the number of terminal electrode boards bonded to the mother board is 16, and the number of times each terminal electrode board is bonded to the mother board is 16. Likewise, suppose a case where the number of circuit modules 1 that can be obtained from a single mother board 30 is 64. In this case, in the method of manufacturing the circuit module 1 according to Preferred Embodiment 1, the number of times each terminal electrode board is bonded to the mother board 30 is 144, whereas in the circuit module manufacturing method according to the related art, the number of times each terminal electrode board is bonded to the mother board is 256.

In the circuit module manufacturing method according to the related art, the terminal electrode board is not diced together when cutting the mother board with a dicer to cut out a plurality of circuit boards from the mother board. Accordingly, the terminal electrode board needs to be mounted onto the mother board in such a way as to avoid a position where the cutting saw passes. However, if the terminal electrode board is mounted onto the mother board with poor accuracy, the terminal electrode board is mounted at a position where the dicing saw passes. Thus, unwanted contact occurs between the dicing saw and the terminal electrode board, leading to poor dimensional accuracy of the outer side surface of the circuit module. Accordingly, in the method of manufacturing the circuit module 1 according to Preferred Embodiment 1, the terminal electrode board 14 is also diced together when cutting the mother board 30 with a dicer to cut out a plurality of circuit boards 11 from the mother board 30. Thus, the dimensional accuracy of the outer side surface of the circuit module 1 can be improved, without deterioration of the dimensional accuracy of the outer side surface of the circuit module due to unwanted contact of the dicing saw with the terminal electrode board.

As described above, in the method of manufacturing the circuit module 1 according to Preferred Embodiment 1 of the present invention, a plurality of terminal electrode boards 14 are mounted on one surface of the mother board 30 from which to cut out a plurality of circuit boards 11. As a result, the same number of terminal electrode boards 14 as the number of circuit boards 11 to be cut out from a single mother board 30 need not be cut out from a single mother board 20. It is thus possible to select a shape or geometry that can maximize the number of terminal electrode boards 14 that can be cut out from a single mother board 20. Since the portion of the mother board 20 not used as the terminal electrode board 14 is reduced, it is possible to minimize material cost, and manufacture the circuit module 1 at low cost. Also, by arranging the terminal electrode board 14 so as to straddle at least a plurality of adjacent circuit boards 11, it is possible to mount a single terminal electrode board 14 onto a plurality of circuit boards 11. Thus, as compared with the case of mounting the terminal electrode board 14 individually onto each of the circuit boards 11, the flatness of the terminal electrode board 14 increases, thereby improving the coplanarity of the circuit module 1. Also, the number of man-hours needed to bond the mother board 30 and each terminal electrode board 14 together decreases, thereby making it possible to minimize operation cost and manufacture the circuit module 1 at low cost.

Further, by reducing the number of terminal electrode boards 14 to be mounted onto the mother board 30, variations in the heights of the terminal electrode boards 14 from the circuit board 1 can be minimized, thereby improving the coplanarity of the circuit module 1. Furthermore, the mother board 30 including a plurality of terminal electrode boards 14 mounted on one surface and a plurality of electronic components 12, 13 mounted on both surfaces is diced at positions where a plurality of circuit boards 11 are to be cut out. Therefore, the side surface of the terminal electrode board 14 can be arranged with good accuracy on the same plane as the outer side surface of the circuit board 11 that has been cut out from the mother board 30.

The method of manufacturing the circuit module 1 described above is an illustrative, non-limiting example. The order in which the electronic components 12, 13, and the terminal electrode board 14 are mounted onto the mother board 30 is not limited to the above-mentioned example.

### Preferred Embodiment 2

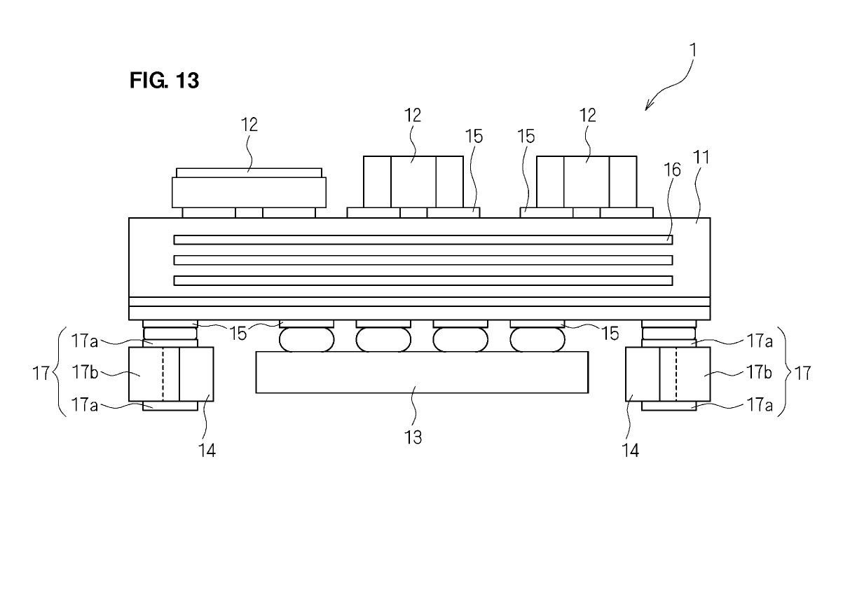

FIG. 13 is a cross-sectional view illustrating the configuration of the circuit module 1 according to Preferred Embodiment 2 of the present invention. As illustrated in FIG. 13, the configuration of the circuit module 1 according to Preferred Embodiment 2 of the present invention preferably is the same or substantially the same as the configuration of the circuit module 1 according to Preferred Embodiment 1 illustrated in FIG. 1, except that in the terminal electrode board 14, the terminal electrode 17 is exposed on the side surface provided on the same plane as the outer side surface of the circuit board 11. Accordingly, in the circuit module 1 according to Preferred Embodiment 2 of the present invention, the same components are denoted by the same symbols, and a detailed description of those components is omitted.

In the circuit module 1 according to Preferred Embodiment 2 of the present invention, the terminal electrode 17 is exposed on the side surface of the terminal electrode board 14 which is provided on the same plane as the outer side surface of the circuit board 11. Thus, when mounting the circuit module to an external apparatus, it is possible to check the bond state between the circuit module 1 and the external apparatus. Specifically, in the case of mounting the circuit module 1 to an external apparatus by bonding the terminal electrode 17 of the terminal electrode board 14 and the external apparatus together by solder or the like, the fillet of the bonded solder or the like is formed on the terminal electrode 17 exposed on the side surface of the terminal electrode board 14 which is provided on the same plane as the outer side surface of the circuit board 11. Thus, the fillet of the solder or the like formed can be visually observed easily, making it possible to check the bond state between the circuit module 1 and the external apparatus.

Next, a description is given of an example of the method of manufacturing the terminal electrode board 14 with the terminal electrode 17 exposed on the side surface that is provided on the same plane as the outer side surface of the circuit board 11. It is to be understood that the manufacturing method described below is a non-limiting example, and any manufacturing method may be used as long as it is possible to manufacture the terminal electrode board 14 with the terminal electrode 17 exposed on the side surface that is provided on the same plane as the outer side surface of the circuit board 11.

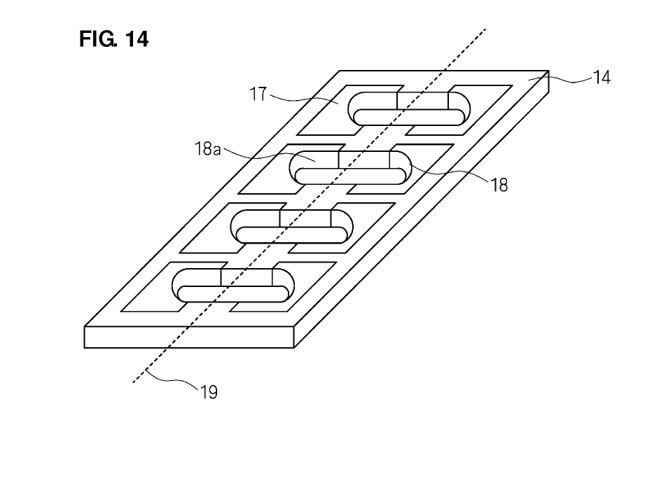

First, as illustrated in FIG. 3, the mother board 20 is diced by using a dicer or the like to cut out a plurality of terminal electrode boards 14 from the mother board 20, thereby forming the terminal electrode boards 14 that preferably are rectangular parallelepiped in shape and each include the terminal electrodes 17 arrayed in two columns and four rows. Further, in Preferred Embodiment 2, each of the terminal electrode boards 14 formed has an opening between a column of the terminal electrodes 17 and a column of the terminal electrodes 17. FIG. 14 is a perspective view of the terminal electrode board 14 according to Preferred Embodiment 2 of the present invention. As illustrated in FIG. 14, the terminal electrode board 14 has an opening 18 between a column of the terminal electrodes 17 and a column of the terminal electrodes 17. The opening 18 corresponds to each row of the terminal electrodes 17, and is formed at a position in each row that partially overlaps each of the terminal electrodes 17. Since the opening 18 is formed at a position that partially overlaps each of the terminal electrodes 17, the terminal electrode 17 is exposed from an inner wall surface 18a of the opening 18.

The terminal electrode board 14 provided with the opening 18 is mounted onto the mother board 30 as illustrated in FIG. 5, and the operations illustrated in FIGS. 6 to 11 are carried out for the mother board 30 with the terminal electrode board 14 mounted, thereby manufacturing the circuit module 1 as illustrated in FIG. 13 with the terminal electrode 17 exposed on the side surface of the terminal electrode board 14 which is provided on the same plane as the outer side surface of the circuit board 11. As the terminal electrode board 14 provided with the opening 18 is diced along a broken line 19, the terminal electrode 17 exposed on the inner wall surface 18a of the opening 18 defines the side surface of the terminal electrode board 14.

As described above, in Preferred Embodiment 2 of the present invention, in the terminal electrode board 14, the terminal electrode 17 is exposed on the side surface that is provided on the same plane as the outer side surface of the circuit board 11. Thus, when mounting the circuit module 1 to an external apparatus, the terminal electrode 17 is exposed on the side surface of the terminal electrode board 14. This allows the bond state between the terminal electrode 17 of the terminal electrode board 14 and the external apparatus to be visually observed easily, making it possible to check the bond state between the circuit module 1 and the external apparatus.

### Preferred Embodiment 3

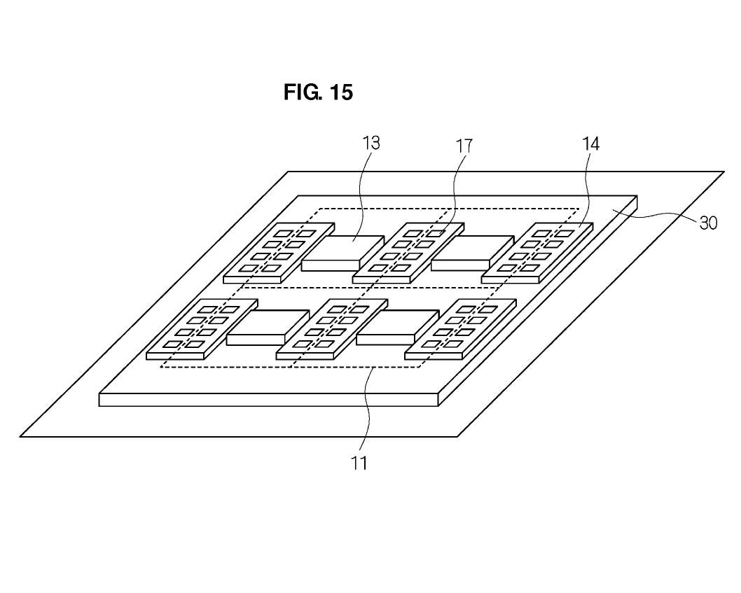

FIG. 15 is a perspective view of the mother board 30 on which a plurality of terminal electrode boards 14 are mounted, according to Preferred Embodiment 3 of the present invention. As illustrated in FIG. 15, the circuit board 11 to be cut out from the mother board 30 preferably has a rectangular or substantially rectangular outer shape in plan view as indicated by a broken line, and the terminal electrode board 14 is arranged and mounted along each of two opposite sides on the outer periphery of each of the circuit boards 11 preferably having a rectangular or substantially rectangular outer shape in plan view. The mother board 30 according to Preferred Embodiment 3 preferably is of the same configuration as the mother board 30 according to Preferred Embodiment 1 illustrated in FIG. 5, except that the terminal electrode board 14 is arranged and mounted along each of two opposite sides on the outer periphery of each of the circuit boards 11. Thus, the same components are denoted by the same symbols, and a detailed description of those components is omitted. Also, the method of manufacturing the circuit module 1 according to Preferred Embodiment 3 of the present invention preferably is the same as the method of the method of manufacturing the circuit module 1 described with reference to Preferred Embodiment 1, except that the terminal electrode board 14 is arranged and mounted along each of two opposite sides on the outer periphery of each of the circuit boards 11. Thus, a detailed description of the manufacturing method is omitted.

As described above, the terminal electrode board 14 is arranged and mounted along each of two opposite sides on the outer periphery of each of the circuit boards 11 preferably having a rectangular or substantially rectangular outer shape in plan view. As a result, the number of terminal electrode boards 14 to be mounted is reduced. Thus, the number of man-hours needed to bond the mother board 30 and each terminal electrode board 14 together decreases, thereby making it possible to minimize operation cost and manufacture the circuit module 1 at low cost.

### Preferred Embodiment 4

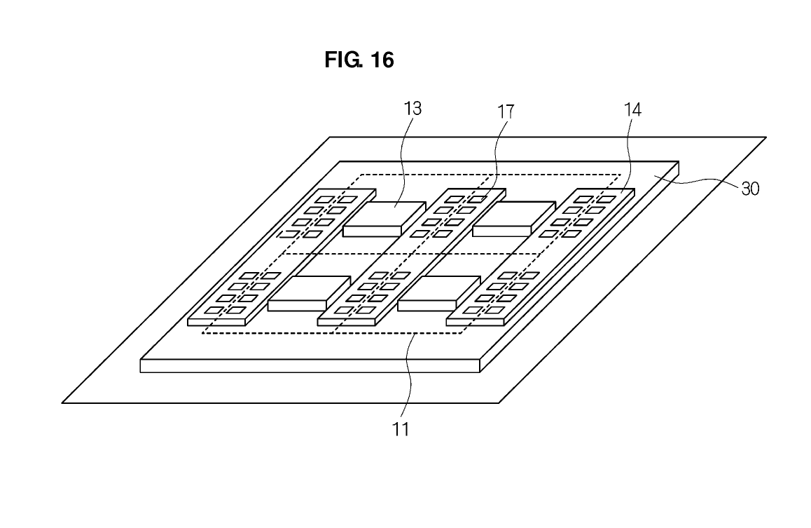

FIG. 16 is a perspective view of the mother board 30 on which a plurality of terminal electrode boards 14 are mounted, according to Preferred Embodiment 4 of the present invention. As illustrated in FIG. 16, the circuit board 11 to be cut out from the mother board 30 preferably has a rectangular or substantially rectangular outer shape in plan view, and the terminal electrode board 14 whose length is at least larger than the length of one side on the outer periphery of the circuit board 11 is arranged and mounted on the mother board 30. The mother board 30 according to Preferred Embodiment 4 is preferably of the same configuration as the mother board 30 according to Preferred Embodiment 1 illustrated in FIG. 5, except that the terminal electrode board 14 whose length is at least larger than the length of one side on the outer periphery of the circuit board 11 to be cut out is arranged and mounted on the mother board 30. Thus, the same components are denoted by the same symbols, and a detailed description of those components is omitted. Also, the method of manufacturing the circuit module 1 according to Preferred Embodiment 4 of the present invention is preferably the same as the method of the method of manufacturing the circuit module 1 described with reference to Preferred Embodiment 1, except that the terminal electrode board 14 whose length is at least larger than the length of one side on the outer periphery of the circuit board 11 to be cut out is arranged and mounted on the mother board 30. Thus, a detailed description of the manufacturing method is omitted.

For example, the terminal electrode board 14 having a length equal to the combined length of two sides on the outer periphery of the circuit board 11 is formed, and is arranged and mounted on the mother board 30. In a case where the terminal electrode board 14 has a length equal to the combined length of two sides on the outer periphery of the circuit board 11, it is possible to arrange the terminal electrode board 14 so as to straddle a maximum of four circuit boards 11 including the circuit boards 11 that are not adjacent to each other. Thus, as compared with a case where the terminal electrode board 14 has a length equal to one side on the outer periphery of the circuit board 11, it is possible to further reduce the number of terminal electrode boards 14 to be mounted onto the mother board 30.

As described above, the terminal electrode board 14 arranged on the mother board 30 has a length at least larger than the length of one side on the outer periphery of the circuit board 11 to be cut out whose outer shape preferably is rectangular or substantially rectangular in plan view. Therefore, it is possible to further reduce the number of terminal electrode boards 14 to be mounted onto the mother board 30. Since the number of man-hours needed to bond the mother board 30 and each terminal electrode board 14 together decreases, it is possible to minimize operation cost, and manufacture the circuit module 1 at low cost. By mounting the circuit module 1 manufactured by the method of manufacturing the circuit module 1 described with reference to Preferred Embodiments 1 to 4, or the circuit module 1 described with reference to Preferred Embodiments 1 to 4, to an electronic component, the electronic apparatus can be manufactured at low cost while achieving miniaturization and weight reduction.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit module manufacturing method for manufacturing a plurality of circuit modules by cutting a mother board including a plurality of electronic components mounted on at least one single surface of the mother board, and cutting out a plurality of circuit boards from the mother board, the method comprising:
a first step of mounting a plurality of terminal electrode boards onto one surface of the mother board, the terminal electrode boards each being arranged so as to straddle at least the circuit boards that are adjacent to each other; and
a second step of cutting the mother board including the terminal electrode boards mounted on the one surface and the electronic components mounted on the at least one single surface, at positions where the circuit boards are to be cut out.

2. The circuit module manufacturing method according to claim 1, wherein:
each of the circuit boards to be cut out from the mother board has a rectangular or substantially rectangular outer shape in plan view; and
in the first step, each of the terminal electrode boards is arranged along each of two opposite sides on an outer periphery of each of the circuit boards.

3. The circuit module manufacturing method according to claim 1, wherein:
each of the circuit boards to be cut out from the mother board has a rectangular or substantially rectangular outer shape in plan view; and
in the first step, each of the terminal electrode boards is arranged along each of four sides on an outer periphery of each of the circuit boards.

4. The circuit module manufacturing method according to claim 1, wherein:
each of the terminal electrode boards includes a plurality of terminal electrodes; and
in the first step, each of the terminal electrode boards is mounted onto the mother board while being arranged so that there are a same number of the terminal electrodes for each of the circuit boards.

5. The circuit module manufacturing method according to claim 1, wherein each of the terminal electrodes included in each of the terminal electrode boards is a via-hole conductor having a conductive paste applied to at least an inner wall surface of a via-hole provided in each of the terminal electrode boards.

6. The circuit module manufacturing method according to claim 1, wherein in each of the terminal electrode boards, each of the terminal electrodes is exposed on a side surface provided on a same plane as an outer side surface of each of the circuit boards.

7. An electronic apparatus comprising the plurality of circuit modules manufactured by the circuit module manufacturing method according to claim 1.

8. A circuit module comprising:
a circuit board;
a plurality of electronic components mounted on at least a single surface of the circuit board; and
a plurality of terminal electrode boards mounted on one surface of the circuit board so that a side surface of each of the terminal electrode boards is arranged on a same plane as an outer side surface of the circuit board.

9. The circuit module according to claim 8, wherein:
the circuit board has a rectangular or substantially rectangular outer shape in plan view; and
each of the terminal electrode boards is arranged along each of two opposite sides on an outer periphery of the circuit board.

10. An electronic apparatus comprising the circuit module according to claim 8.
